(19) United States
(12) Patent Application Publication
(10) Pub. No.: US 2012/0223293 A1
(43) Pub. Date: Sep. 6, 2012

(54) Biodegradable Electronic Devices

(76) Inventors: Jeffrey T. Borenstein, Newton, MA (US); Chris Bettinger, Boston, MA (US); Robert Langer, Newton, MA (US); David Kaplan, Concord, MA (US)

(21) Appl. No.: 11/969,646

(22) Filed: Jan. 4, 2008

Related U.S. Application Data
(60) Provisional application No. 60/878,859, filed on Jan. 5, 2007.

(51) Int. Cl. H01L 51/30; H01L 51/40

(52) U.S. Cl. 257/40; 438/1; 257/E51.007; 257/E51.025

(57) ABSTRACT

Biodegradable electronic devices may include a biodegradable semiconducting material and a biodegradable substrate layer for providing mechanical support to the biodegradable semiconducting material.

### CROSS-REFERENCE TO RELATED APPLICATION

This application claims the benefit of and priority to U.S. Provisional Patent Application No. 60/878,859, filed Jan. 5, 2007, the disclosure of which is hereby incorporated herein by reference in its entirety.

### TECHNICAL FIELD

The present invention generally relates to biodegradable electronic devices and to methods for fabricating the same.

### BACKGROUND

Current microelectromechanical electrical systems for biological applications (“BioMEMS”) are typically fabricated using materials and processes that have been directly adapted from, or are closely related to, the semiconductor industry. For example, bulk-materials processing and microfabrication strategies for biosensors are typically fine-tuned for silicon and silicon compounds such as silicon dioxide. Other materials, such as gold or platinum, are often also used as conducting materials for a variety of BioMEMS applications, including neurological applications. However, these materials are generally not resorbable and structures made of these materials may maintain their configurations for a long period of time. Therefore, when used in substantial amounts and/or for structural configuration, these materials may not be suitable for various applications (e.g., implantable, biomedical, and/or security-related applications) that require properties such as biodegradability, or may present health, safety, security, and environmental concerns.

### SUMMARY OF THE INVENTION

In various embodiments, the present invention utilizes biodegradable materials to fabricate a biodegradable electronic device. Electronic devices fabricated from biodegradable materials, completely or in part, possess, in accordance with embodiments of the invention, mechanical, electrical, and biological properties that are compatible with medical, implantable, agricultural, environmental, and security applications.

As used herein, the term “biodegradable materials” refers in general to materials that have a chemical structure that may be altered by common environmental chemistries (e.g., enzymes, pH, and naturally-occurring compounds) to yield elements or simple chemical structures that may be resorbed by the environment without harm thereto. The term “biocompatible materials” refers in general to materials that not harmful to the environment. The environment may be an in vivo environment or an environment outside the body, for example, in a crop field, and environmental chemistries may vary among naturally occurring environments. Biodegradable materials are different from bioerodible materials in that the principle mode of mass loss is chemical loss in the case of biodegradable materials versus physical loss in the case of bioerodible materials. For example, biodegradable materials may be broken down into elements or chemical structures, whereas bioerodible materials may be broken down (e.g. chain scission) at a macroscopic level with chemical structures that remain largely intact.

In various embodiments, the present invention allows for the use of electronic devices in a variety of in vivo biomedical applications without having to retrieve the devices and/or their components because they are completely resorbable, partially resorbable, and/or not harmful to the in vivo environment. The electronic devices described herein may also have a variety of extracorporeal uses (e.g., in agricultural assessments, environmental monitoring, and/or security applications) from which they need not be retrieved because they are capable of degrading into materials that are not harmful to the environment and/or into components that are not readily identifiable as part of a man-made device.

In general, in one aspect, the invention features an active biodegradable electronic device that includes an active layer having a biodegradable semiconducting material. In various embodiments, the device also includes a biodegradable substrate layer for providing mechanical support to the active layer, and a biodegradable dielectric layer between the biodegradable substrate layer and the active layer.

In general, in another aspect, the invention features a biodegradable electronic device that includes a biodegradable semiconducting material and a biodegradable substrate layer for providing mechanical support to the biodegradable semiconducting material.

In general, in yet another aspect, the invention features a biodegradable electronic device that includes a biodegradable semiconducting material. A first portion of the biodegradable semiconducting material is treated with a biocompatible electropositive agent and a second portion of the biodegradable semiconducting material is treated with a biocompatible electronegative agent.

In general, in still another aspect, the invention features a method of fabricating a biodegradable electronic device. The method includes employing a biodegradable substrate layer to mechanically support a biodegradable semiconducting material. In various embodiments, the method further includes applying a biodegradable dielectric layer to the biodegradable substrate layer and applying the biodegradable semiconducting material to the biodegradable dielectric layer. The biodegradable semiconducting material may serve as an active layer in an active biodegradable electronic device.

Various embodiments of these biodegradable electronic devices, and of these methods of fabricating the biodegradable electronic devices, include the following features. At least one contact may be positioned or formed on the biodegradable semiconducting material. For example, where the biodegradable electronic device is a field-effect transistor (i.e., an active electronic device that controls the flow of electrons therethrough), source and drain contacts may be positioned or formed on the active layer, and a gate contact may be positioned or formed between the biodegradable substrate layer and the biodegradable dielectric layer. The contacts may each be formed from a biocompatible material, such as gold.

The biodegradable dielectric layer may include a natural polymer, such as a protein, a polysaccharide, or silk, or a synthetic polymer, such as a polyester. The biodegradable semiconducting material may include a natural polymer, a synthetic polymer, a natural protein, a synthetic protein, a natural (typically organic) pigment, and/or a synthetic organic pigment. In certain embodiments, the biodegradable semiconducting material includes melanin.

The biodegradable electronic devices may be integrated with each other to produce a variety of complex, biodegradable electronic systems for numerous applications. Accordingly, in another aspect, the invention features a biodegradable electronic system that includes at least one biodegradable electronic device. The biodegradable electronic device includes a biodegradable semiconducting material and a biodegradable substrate layer for providing mechanical support to the biodegradable semiconducting material. In various embodiments, the biodegradable electronic system is, for example, a memory chip, an RFID tag, a vanishing tag, and/or a processor.

### BRIEF DESCRIPTION OF THE DRAWINGS

The foregoing and other objects, aspects, features, and advantages of the invention will become more apparent and may be better understood by referring to the following description taken in conjunction with the accompanying drawings, in which:

FIG. 1 schematically illustrates a layered stack structure for a biodegradable electronic device, for example a field effect transistor or FET, in accordance with one embodiment of the invention;

FIG. 2 schematically illustrates a layered stack structure for a biodegradable electronic device, for example a bipolar junction transistor or BJT, in accordance with one embodiment of the invention;

FIG. 3 schematically illustrates a layered stack structure for a biodegradable electronic device, for example a diode, in accordance with one embodiment of the invention;

FIG. 4 schematically illustrates a layered stack structure for a biodegradable electronic device, for example a Schottky diode, in accordance with one embodiment of the invention;

FIG. 5 schematically illustrates a layered stack structure for a biodegradable electronic device, for example a capacitor, in accordance with one embodiment of the invention; and

FIG. 6 schematically illustrates a layered stack structure for a biodegradable electronic device, for example an optical device, in accordance with one embodiment of the invention.

### DESCRIPTION

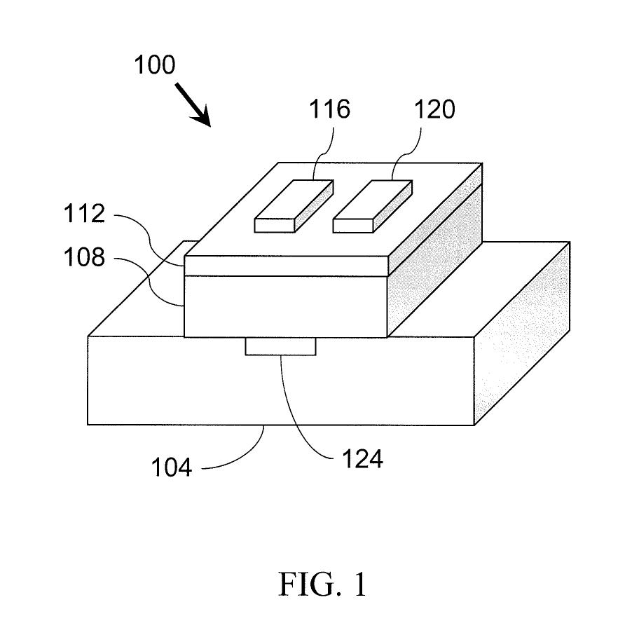

In certain embodiments, with reference to FIG. 1, the invention relates to an electronic device 100 that includes three layers in a stack—a biodegradable substrate layer 104, a biodegradable dielectric layer 108, and an active layer 112. As depicted in FIG. 1, the electronic device 100 may include three points of contact—a source contact 116 and a drain contact 120 positioned on the active layer 112, and a gate contact 124 positioned between the biodegradable substrate layer 104 and the biodegradable dielectric layer 108.

While the particular electronic device 100 described with reference to FIG. 1 is a biodegradable FET 100 (i.e., an active electronic device), those skilled in the art will understand that the invention is not limited solely to FETs or active electronic devices (i.e., devices that control the flow of electrons therethrough). Rather, as described further below, any active or passive biodegradable electronic device may be built using, in various combinations and permutations, the biodegradable dielectric, biodegradable semiconducting, and/or biodegradable conducting materials described with reference to FIG. 1. Thus, all such biodegradable electronic devices are within the scope of the invention.

A wide range of biodegradable materials may be used in the biodegradable electronic device 100 (e.g., distinct biodegradable materials may be used for each component), and the physical properties of the biodegradable materials may mirror those of materials that have been used in traditional organic thin-film microelectronic applications. However, unlike traditional organic thin-film microelectronic applications, in one embodiment of the present invention, the active layer 112 of the biodegradable electronic device 100 comprises, or consists essentially of a semiconducting material that is biodegradable, such as a polymer, a protein, and/or a pigment (e.g., melanin).

The use of biodegradable materials in the electronic devices described herein presents several advantages over non-degradable devices, which can pose adverse health, environmental, safety, and security considerations. Moreover, the biodegradable electronic devices are electrically active and useful because of the specific nature of the biodegradable materials used.

Libraries of available biodegradable materials, both natural and synthetic, provide a spectrum of physical properties that allow for the fabrication of biodegradable electronic components tailored to various applications. In certain embodiments, the present invention utilizes materials such as collagens, chitosan, various forms of silk (e.g., silkworm fibroin, modified silkworm fibroin, spider silk, insect silk, or genetically engineered silk), and/or electrically conducting polymers to build the biodegradable electronic devices.

More specifically, in certain embodiments, the active layer 112 of the biodegradable electronic device 100 comprises, or consists essentially of, a biodegradable semiconducting material, such as a polymer, a protein, and/or an organic pigment. These materials may be derived from natural sources or produced synthetically by processes known in the art. For example, the biodegradable semiconducting material of the active layer 112 may be melanin. Natural and synthetic forms of melanin may be obtained, for example, through chemical suppliers such as Sigma Aldrich (Catalogue #M2649 and #M8631, respectively). Natural melanin may be isolated from the Sepia officinalis (cuttlefish), which utilizes melanin as a pigment for camouflage. Synthetic melanin my prepared by oxidizing tyrosine in the presence hydrogen peroxide.

The biodegradable semiconducting material of the active layer 112 also may comprise, or consist essentially of, aromatic amino acids and their oligomers/polymers, porphyrin based proteins, block copolymers of synthetic conducting polymers if biodegradable blocks are sufficiently frequent to generate low molecular weight fragments, and metallized biopolymers. Each of these materials, including the melanin, has adequate mechanical properties, may be solution processible, and is biodegradable. In addition, the semiconducting nature of each of these materials, including the melanin, provides a suitable active layer 112 for the biodegradable electronic device 100. In particular, as described below, each material may be tested and, for example, the dimensions (e.g., thickness) and/or smoothness/roughness of the active layer 112 (or of the other layers 104, 108) routinely optimized so as to provide a suitable active layer 112 for the flow of current between the drain 120 and source 116 when the biodegradable electronic device 100 is used as a FET.

In certain embodiments, the biodegradable dielectric layer 108 comprises, or consists essentially of, non-conducting biodegradable materials, such as polymers (e.g., polyester), proteins (e.g., collagens), and/or polysaccharides (e.g., chitosan). For example, the biodegradable dielectric layer 108 may comprise, or consist essentially of, silk (e.g., silkworm fibroin, modified silkworm fibroin, spider silk, insect silk, or genetically engineered silk). The biodegradable dielectric layer 108 may also comprise, or consist essentially of, poly(glycerol-sebacate) (“PGS”), which is a synthetic flexible biodegradable elastomer; polydioxanone; and/or poly(lactic-co-glycolic acid) (“PLGA”). Each of these materials has desirable mechanical properties and is biodegradable. In addition, the insulating nature of each of these materials provides a suitable dielectric layer for the biodegradable electronic device 100.

The biodegradable substrate layer 104 may be formed from biodegradable insulating materials, or from biodegradable conducting materials, depending on the configuration of the device 100 and the desired function of the biodegradable substrate layer 104. For example, if, as shown in FIG. 1, the gate contact 124 is positioned between the biodegradable substrate layer 104 and the biodegradable dielectric layer 108, then the biodegradable substrate layer 104 may comprise, or consist essentially of, an insulating biodegradable polymer, such as any one of those described above for the biodegradable dielectric layer 108. However, the biodegradable substrate layer 104 may also comprise a sandwich structure, in which a thin layer of an insulating biodegradable polymer is formed on top of another, thicker biodegradable substrate with arbitrary electrical properties. In general, the biodegradable substrate layer 104 provides mechanical support for the other components of the biodegradable electronic device 100.

As noted above, in one embodiment, the electronic device 100 includes three electrical contacts—a source contact 116, a drain contact 120, and a gate contact 124. The contacts 116, 120, 124 are conductive and may be fabricated to comprise, or consist essentially of, gold, a conductive material that is known to be bio-inert. However, in other embodiments, conductive, biodegradable materials are used to fabricate the contacts 116, 120, 124. For example, a biodegradable electrically conducting polymer (“BECP”), melanin, aromatic amino acids and their oligomers/polymers, porphyrin based proteins, block copolymers of synthetic conducting polymers if degradable blocks are sufficiently frequent to generate low molecular weight fragments, and metallized biopolymers may be used for the contacts 116, 120, 124. Alternatively, a conductive, erodible polymer, such as poly(pyrrole) (“ePPy”), polyaniline, polyacetyline, poly-p-phenylene, poly-p-phenylene-vinylene, polythiophene, and hemosin may be used as the conductive material in one or more of the contacts 116, 120, 124. Other erodible, conducting polymers (for example as described in Zelikin et al., Erodible Conducting Polymers for Potential Biomedical Applications, Angew. Chem. Int. Ed. Engl., 2002, 41(1):141-144) may also be used as the conductive material in one or more of the contacts 116, 120, 124.

As depicted in FIG. 1, the role of the gate 124 is to provide a conducting region that overlies the device channel, overlapping with the source 116 and drain 120 regions in the x-y plane but at a different location along the z axis. This standard transistor geometry facilitates the modulation of current within the active layer 112. The dielectric layer 108 between the gate 124 and the active layer 112 prevents, as in traditional silicon-based transistors, shorting of the circuit.

The embodiment shown in FIG. 1 includes an individual patterned gate contact 124 in conjunction with the biodegradable substrate layer 104. Since the gate 124 is patterned, it is aligned with the source 116 and drain 120 contacts to ensure proper overlap, which in turn induces the proper field effect. In an electronic system (e.g., a memory chip, an RFID tag, a vanishing tag, or a processor) having multiple biodegradable electronic devices arranged in a conventional transistor logic configuration, the substrate layer 104 may be used to isolate and insulate the patterned gate 124 of one biodegradable electronic device 100 from the gates 124 (or other contacts) in other biodegradable electronic devices 100, thereby allowing multiple biodegradable electronic devices 100 to be interconnected in a circuit and to thereby function in the electronic system.

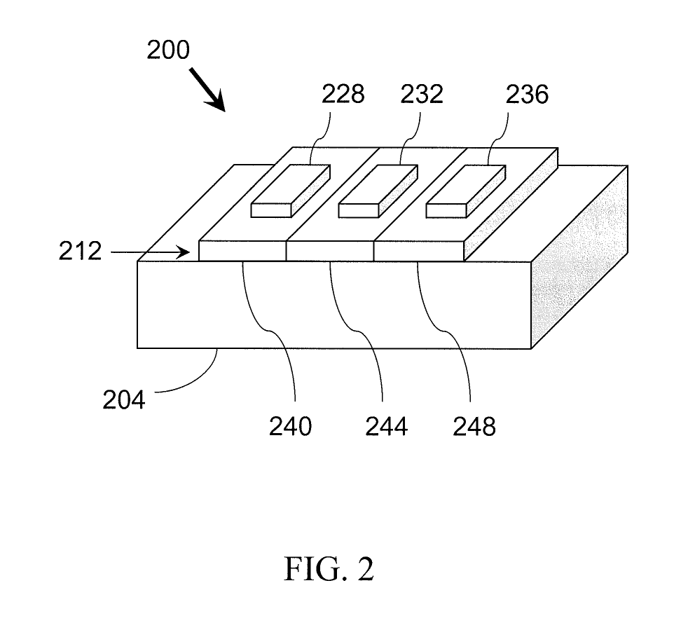

In certain embodiments, the materials used to construct the electronic device 100 allow the device 100 to be fully biodegradable (i.e., vanishing) and/or compatible with human implantation. Accordingly, the devices 100, 200, 300, 400, 500, 600 described herein (see, also, FIGS. 2-6) may be employed in, for example, vanishing tags or markers for tracking products, goods, animals, and humans, security and safety applications, and “green chemistry” and environmentally friendly applications. In addition, in vitro and implantable devices that provide a specific biological or medical function may be prepared using the biodegradable devices 100, 200, 300, 400, 500, 600 described herein.

Fabrication strategies have been developed for the manufacture of microstructures using biodegradable materials as substrates with sub-micron scale precision. Applying these generalized microfabrication strategies to other biomaterials with appropriate physical properties facilitates manufacture of electronic devices. Furthermore, electronic systems comprising such biodegradable electronic devices, for example, memory chips, RFID tags, vanishing tags, and processors, may be manufactured in accordance with standard techniques of manufacture for such systems.

The fabrication of the biodegradable electronic device 100 depicted in FIG. 1 may be achieved through a series of steps. For example, in certain embodiments, the biodegradable substrate layer 104 is formed by solubilization or melt processing. Alternatively, the biodegradable substrate layer 104 may be purchased as sheet stock much like silicon wafers are purchased. In general, the surface of the biodegrade substrate layer 104 should be substantially flat on both the macroscale and the microscale levels. In certain embodiments, a biodegradable substrate layer 104 is formed as a planar biodegradable polymer film via solubilization of the polymer, followed by known deposition techniques, such as spincoating, melt processing, hot pressing, and/or dropwise, spray, and/or dipping techniques. To form the biodegradable dielectric layer 108, a dilute solution of a biodegradable insulating polymer, such as silk (e.g., those silks enumerated above), PGS, polydioxanone, PLGS, or another biodegradable natural insulating polymer in an organic solvent such as 1,1,1,3,3,3-hexafluoroisopropanol may be spincoated onto the surface of the biodegradable substrate layer 104, followed by crosslinking by chemical, thermal, or photopolymerization treatments. Next, to form the active layer 112, a dilute aqueous solution of a biodegradable semiconducting material, for example melanin in 1M NaOH, may be spincoated on the stack of layers, which may be followed by post-baking. In certain embodiments, a photolithographic lift-off process may be performed to produce the source contact 116 and drain contact 120. The gate contact 124 may be fabricated via vacuum sputtering of gold through a shadow mask to create features with micron scale resolution.

The layers 104, 108, 112 of the device 100 may be characterized by microscopy methods as well as measurements of physical properties. For example, for small devices, such as BioMEMS devices, film layers of the device may be examined by scanning electron microscopy (“SEM”) and atomic force microscopy (“AFM”) to characterize the morphology of each film layer including thickness and roughness. Film layer composition and thickness may be verified by attenuated total reflectance FT-IR and ellipsometry, respectively.

In one embodiment of the invention, as described, the biodegradable electronic device 100 is a biodegradable FET. The dimensions and tolerances of the device components may be chosen conservatively. For example, in a representative embodiment, the device dimensions include an active layer 112 of approximately 50 nm in thickness, a biodegradable dielectric layer 108 of 500 nm in thickness, and a gate 124 width of between 20 and 200 microns. For the biodegradable substrate layer 104, the required thickness may determined by mechanical strength and handling considerations, such as the desire for flexibility/bending versus ease of handling. Cost may also be considered in choosing the thickness of the biodegradable substrate layer 104. Typical biodegradable substrate layer 104 thickness may be in the range of 200-1000 microns. Dimensions for the source 116 and drain 120 contacts are largely driven by the target size for the device 100. These dimensions are compatible with high-density transistor arrays and may be achieved through the use of known processes, for example electroplating processes, spincoating processes, and/or high-resolution lithographic processes, known to those skilled in the art.

The fundamental electronic properties (including conductivity and mobility) of each specific material and layer 104, 108, 112 of the device 100 may be readily characterized. More specifically, electrical and field-effect properties of the biodegradable FET 100 may be calculated using standard preliminary testing techniques, which may be conducted to obtain data regarding the drain current (“I_{D}”) and the source-drain voltage (“V_{SD}”). The dimensions of the layers 104, 108, 112 may then be altered as necessary to overcome any limitations by the switching property of any one or more materials (e.g., melanin) in the active layer 112. Once the parameter space for V_{SD} has been properly identified, I_{D} may be measured as a function of the gate voltage (“V_{G}”). Field-effect parameters such as the mobility of electrons within the active layer 112 may also be examined, and the dimensions (e.g., thicknesses) of the layers 104, 108, 112, their smoothness/roughness, the materials used therein, and their chemical properties may be routinely optimized to achieve the desired electron mobility.

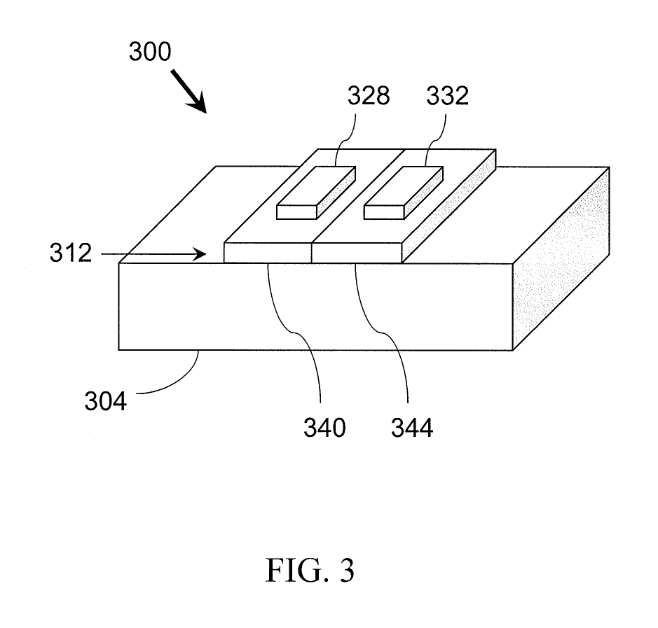

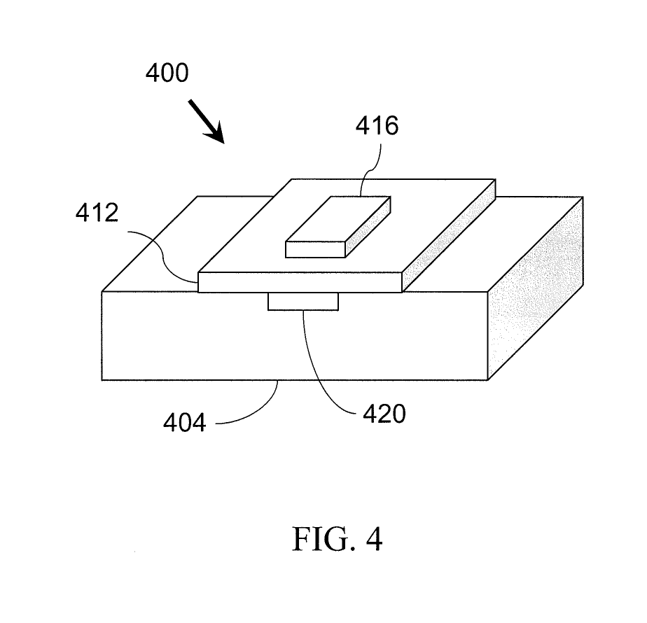

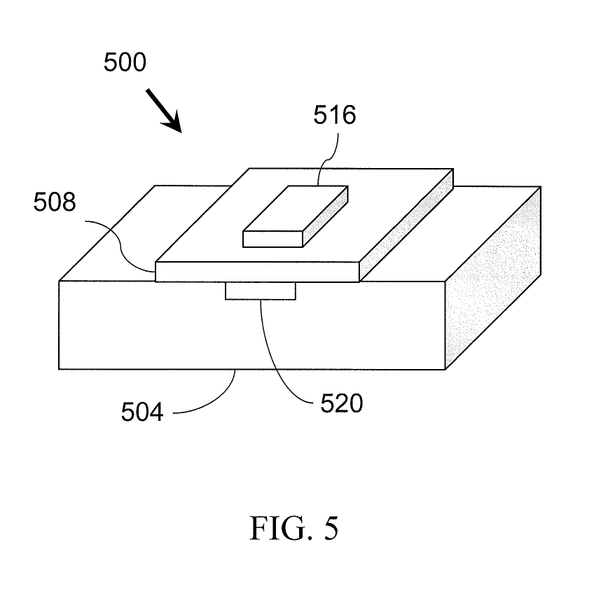

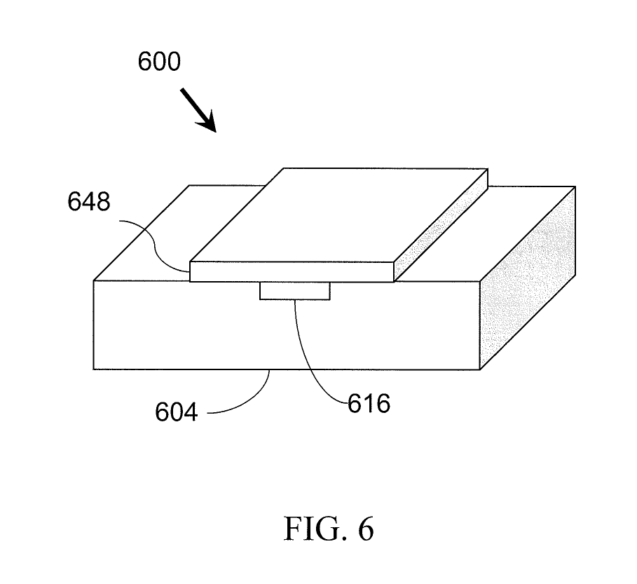

While the description above has been presented with respect to an exemplary biodegradable FET 100, those skilled in the art will understand that the materials and methods described above may be used to fabricate any other type of biodegradable electronic device. For example, the above-described biodegradable dielectric, biodegradable semiconducting, and biodegradable conducting materials may be combined in various combinations and permutations to fabricate other biodegradable electronic devices including, but not limited to, biodegradable BJTs 200 (see FIG. 2), biodegradable diodes 300 (see FIG. 3), biodegradable Schottky diodes 400 (see FIG. 4), biodegradable capacitors 500 (see FIG. 5), biodegradable optical devices 600 (see FIG. 6), various sensors and displays, MOS-type capacitors, and other field effect devices.

For example, with reference to FIG. 2, a biodegradable BJT 200 that includes two layers in a stack—a biodegradable substrate layer 204 and an active layer 212—may be fabricated. The BJT 200 may include three points of contact—an emitter contact 228 positioned on an emitter region 240 of the active layer 212, a base contact 232 positioned on a base region 244 of the active layer 212, and a collector contact 236 positioned on a collector region 248 of the active layer 212.

A wide range of biodegradable materials may be used to fabricate the biodegradable BJT 200, and distinct biodegradable materials may be used for each component and/or region. For example, the biodegradable substrate layer 204 of the BJT 200 may be formed from the biodegradable materials described above for the biodegradable substrate layer 104 of the device 100 depicted in FIG. 1. Moreover, the active layer 212 of the BJT 200 may comprise, or consist essentially of, the biodegradable semiconducting materials described above for the active layer 112 of the device 100, and each of the emitter contact 228, the base contact 232, and the collector contact 236 may comprise, or consist essentially of, a bio-inert material, such as gold, or the biodegradable conducting materials described above for the source 116, drain 120, and gate 124 contacts of the device 100.

In one embodiment, to mimic the p-n-p junctions seen in traditional silicon-based devices, the emitter and collector regions 240, 248 of the biodegradable semiconducting material may be treated or augmented with a biocompatible electropositive agent to mimic p-doped regions, and the base region 244 of the biodegradable semiconducting material may be treated or augmented with a biocompatible electronegative agent to mimic an n-doped region. Alternatively, in another embodiment, to mimic the n-p-n junctions seen in traditional silicon-based devices, the emitter and collector regions 240, 248 of the biodegradable semiconducting material may be treated or augmented with a biocompatible electronegative agent to mimic n-doped regions, and the base region 244 of the biodegradable semiconducting material may be treated or augmented with a biocompatible electropositive agent to mimic an p-doped region.

Methods for treating or augmenting the biodegradable semiconducting material of the active layer 212 to mimic a p- or n-doped region include, for example, treatment with a biocompatible oxidizing agent or reducing agent, respectively. Biocompatible oxidizing agents may include O₂, O₃, F₂, Cl₂, Br₂, and I₂. Biocompatible reducing agents may include Li, Na, Mg, Al, H₂, Cr, Fe, Sn²⁺, Cu²⁺, Ag, 2Br⁻, and 2Cl⁻. In one embodiment, biodegradable semiconducting polymers of the active layer 212 are doped using oxidation-reduction chemical processes, for example, by exposing the polymer to a biocompatible oxidizing agent or to a biocompatible reducing agent. Alternatively, in another embodiment, biodegradable semiconducting polymers of the active layer 212 are doped by electrochemical processes, for example, by suspending an electrode coated with the polymer in an electrolyte solution in which the polymer is insoluble along with a separate counter and reference electrodes.

Those skilled in the art will understand that the active layer 112 of the device 100 described above with respect to FIG. 1, or portions thereof, may be similarly treated or augmented with biocompatible oxidizing or reducing agents to mimic the p- or n-doped regions of traditional silicon-based devices, thereby increasing its conductivity.

Another exemplary biodegradable electronic device, a biodegradable diode 300, is depicted in FIG. 3. As depicted, the biodegradable diode 300 may include two layers in a stack—a biodegradable substrate layer 304 and a biodegradable semiconducting layer 312. The diode 300 may also include two points of contact—an anode contact 328 positioned on a p-type region 340 of the semiconducting layer 312 and a cathode contact 332 positioned on an n-type region 344 of the semiconducting layer 312. Again, the biodegradable materials described in detail above with respect to FIGS. 1 and 2 may be used in the biodegradable diode 300. For example, the biodegradable substrate layer 304 may be formed from the biodegradable materials described above for the biodegradable substrate layer 104 of the device 100 depicted in FIG. 1. Each of the anode 328 and cathode 332 contacts may comprise, or consist essentially of, a bio-inert material, such as gold, or the biodegradable materials described above for the contacts 116, 120, and 124 of the device 100.

The biodegradable semiconducting layer 312 of the diode 300 may comprise, or consist essentially of, the biodegradable semiconducting materials described above for the active layer 112. Again, as described above with respect to the emitter, base, and collector regions 240, 244, and 248 of the BJT 200, the p-type and n-type regions 340, 344 of the biodegradable diode 300 may be treated or augmented with a biocompatible oxidizing agent or reducing agent, respectively.

Additional exemplary biodegradable electronic devices include biodegradable Schottky diodes 400, biodegradable capacitors 500, and biodegradable optical devices 600. With reference first to FIG. 4, a biodegradable Schottky diode 400 may include two layers in a stack—a biodegradable substrate layer 404 and a biodegradable semiconducting layer 412. The Schottky diode 400 may also include two points of contact—a first conducting contact 416 positioned on the biodegradable semiconducting layer 412, and a second conducting contact 420 positioned between the biodegradable substrate layer 404 and the biodegradable semiconducting layer 412. With reference to FIG. 5, a biodegradable capacitor 500 may also include two layers in a stack—a biodegradable substrate layer 504 and a biodegradable dielectric layer 508. The capacitor 500 may also include two points of contact—a first conducting contact 516 positioned on the dielectric layer 508, and a second conducting contact 520 positioned between the biodegradable substrate layer 504 and the biodegradable dielectric layer 508. With reference to FIG. 6, a biodegradable optical device 600 may include two layers in a stack—a biodegradable substrate layer 604 and a biodegradable, optically-active layer 648. The optical device 600 may also include a single point of contact—a conducting contact 616 positioned between the biodegradable substrate layer 604 and the optically-active layer 648.

As before, biodegradable materials may be used to fabricate the biodegradable Schottky diode 400, the biodegradable capacitor 500, and the biodegradable optical device 600. For example, the biodegradable substrate layers 404, 504, 604 may be formed from the biodegradable materials described above for the biodegradable substrate layer 104 of the device 100 depicted in FIG. 1. Each of the contacts 416, 420, 516, 520, 616 may comprise, or consist essentially of, a bio-inert material, such as gold, or the biodegradable conducting materials described above for the contacts 116, 120, and 124 of the device 100. The biodegradable semiconducting layer 412 of the Schottky diode 400 may comprise, or consist essentially of, the biodegradable semiconducting materials described above for the active layer 112 of the device 100. The dielectric layer 508 of the capacitor 500 may comprise, or consist essentially of, the insulating materials described above for the dielectric layer 108 of the device 100. Finally, the biodegradable, optically-active layer 648 of the biodegradable optical device 600 may comprise, or consist essentially of, biodegradable materials including, but not limited to, natural or synthetic melanin and optically active proteins such as green fluorescent protein (GFP).

As will be understood by one skilled in the art, the fundamental electrical properties of the above described exemplary biodegradable electronic devices 200, 300, 400, 500, 600 may be achieved and set to mimic, or to approximate within an acceptable threshold, those of their counterpart traditional silicon-based devices by routinely optimizing the dimensions (e.g., thicknesses) of the various layers employed in the devices, their smoothness/roughness, the materials used therein, their chemical properties, the microscale morphology, and the molecular packing.

The above-described materials and methods may be used as building blocks with which to fabricate more complex electronic systems that include various biodegradable electronic devices. Such systems, include, but are not limited to, memory chips, RFID tags, vanishing tags, sensors, optical devices, and processors. The biodegradable electronic devices described herein are useful for numerous applications in the medical, agricultural, and defense industries, for example as follows.

Biomedical Applications. The realization of biodegradable electronic devices provides base technology for implantable or injectable integrated electronic BioMEMS systems for, e.g., biosensing or drug-delivery applications. These systems may also be implanted for temporary monitoring of neurological activity through RFID technology. Additionally, a biodegradable drug-delivery device equipped with biodegradable integrated circuit technology may be triggered to release drugs using external RFID sources. Moreover, networks of biodegradable electronic devices may also be used for temporarily monitoring neurological activity. Such a network may also be interfaced with RFID technology to provide a rapid, on-demand drug delivery system for the brain to treat neurological orders with rapid onsets such as epilepsy.

Agricultural Applications. Complex electronic systems comprising biodegradable electronic devices with biodegradable polymers may include, for example, temporary environmental sensors to assess parameters such as soil pH or nitrogen content. These sensors may be spread across large areas to produce a sensor network, which will eventually degrade. The biodegradable properties of these devices complement efforts to develop environmentally friendly chemistries.

Environmental Systems. Complex electronic systems comprising biodegradable electronic devices may be used, for example, as sensors to determine a wide variety of environmental conditions including the presence of spoilage, toxins, and other potential sources of health problems in water supplies. These sensors may be placed indiscriminately throughout the geographical area to be surveyed to produce a network of sensors. This distributed network of sensors may then communicate between itself and a centralized network using conventional RF communication capabilities.

Security Applications. Widespread networks of low-cost biodegradable sensors may be distributed across large areas to function as temporary sensors for military operations. These networks might serve their sensor function and then degrade in environmental conditions. This degradation property may be beneficial for these specific applications for various reasons. First, the technology that is based in the sensor may degrade fairly quickly and therefore limit the potential for detection in a hostile environment. Second, the sensors will have no permanent impact on the immediate environment.

Having described certain embodiments of the invention, it will be apparent to those of ordinary skill in the art that other embodiments incorporating the concepts disclosed herein may be used without departing from the spirit and scope of the invention. Accordingly, the described embodiments are to be considered in all respects as only illustrative and not restrictive.

What is claimed is:

1. An active biodegradable electronic device, comprising:
an active layer comprising a biodegradable semiconducting material.

2. The device of claim 1 further comprising a biodegradable substrate layer for providing mechanical support to the active layer.

3. The biodegradable device of claim 2 further comprising a biodegradable dielectric layer between the biodegradable substrate layer and the active layer.

4. The device of claim 3 further comprising source and drain contacts on the active layer and a gate contact between the biodegradable substrate layer and the biodegradable dielectric layer.

5. The device of claim 4, wherein the source, drain, and gate contacts each comprise a biocompatible material.

6. The device of claim 5, wherein the biocompatible material is gold.

7. The device of claim 3, wherein the biodegradable dielectric layer comprises a biodegradable material selected from the group consisting of a natural polymer, a protein, a polysaccharide, and silk.

8. The device of claim 1, wherein the biodegradable semiconducting material is selected from the group consisting of a natural polymer, a synthetic polymer, a natural protein, a synthetic protein, a natural pigment, and a synthetic pigment.

9. The device of claim 1, wherein the biodegradable semiconducting material comprises melanin.

10. A biodegradable electronic device, comprising:
a biodegradable semiconducting material; and
a biodegradable substrate layer for providing mechanical support to the biodegradable semiconducting material.

11. The device of claim 10 further comprising at least one contact on the biodegradable semiconducting material.

12. The device of claim 10, wherein the biodegradable semiconducting material is selected from the group consisting of a natural polymer, a synthetic polymer, a natural protein, a synthetic protein, a natural pigment, and a synthetic pigment.

13. The device of claim 10, wherein the biodegradable semiconducting material comprises melanin.

14. A method of fabricating a biodegradable electronic device, the method comprising the steps of:
employing a biodegradable substrate layer to mechanically support a biodegradable semiconducting material.

15. The method of claim 14 further comprising applying a biodegradable dielectric layer to the biodegradable substrate layer and applying the biodegradable semiconducting material to the biodegradable dielectric layer.

16. The method of claim 15 further comprising forming source and drain contacts on the biodegradable semiconducting material and a gate contact between the biodegradable substrate layer and the biodegradable dielectric layer.

17. The method of claim 16, wherein the source, drain, and gate contacts each comprise a biocompatible material.

18. The method of claim 17, wherein the biocompatible material is gold.

19. The method of claim 15, wherein the biodegradable dielectric layer comprises a biodegradable material selected from the group consisting of a natural polymer, a protein, a polysaccharide, and silk.

20. The method of claim 14, wherein the biodegradable semiconducting material is selected from the group consisting of a natural polymer, a synthetic polymer, a natural protein, a synthetic protein, a natural pigment, and a synthetic pigment.

21. The method of claim 14, wherein the biodegradable semiconducting material comprises melanin.

22. The method of claim 14, wherein the biodegradable semiconducting material serves as an active layer in an active biodegradable electronic device.

23. A biodegradable electronic device, comprising:
a biodegradable semiconducting material, a first portion of the biodegradable semiconducting material having been treated with a biocompatible electropositive agent and a second portion of the biodegradable semiconducting material having been treated with a biocompatible electronegative agent.

24. A biodegradable electronic system, comprising:
at least one biodegradable electronic device comprising:
a biodegradable semiconducting material; and
a biodegradable substrate layer for providing mechanical support to the biodegradable semiconducting material.

25. The biodegradable electronic system of claim 24, wherein the system is selected from the group consisting of a memory chip, an RFID tag, a vanishing tag, and a processor.
